(19) United States
(12) Patent Application Publication
(10) Pub. No.: US 2024/0083135 A1
(43) Pub. Date: Mar. 14, 2024

(54) WATERPROOF SOUND-TRANSMITTING SHEET

(71) Applicant: AMOGREENTECH CO., LTD., Gimpo-si, Gyeonggi-do (KR)

(72) Inventors: Kangsik SHIN, Gimpo-si (KR); Kyoungtaek PARK, Gimpo-si (KR)

(73) Assignee: AMOGREENTECH CO., LTD., Gimpo-si, Gyeonggi-do (KR)

(21) Appl. No.: 18/273,012

(22) PCT Filed: Jan. 18, 2022
(86) PCT No.: PCT/KR2022/000923

§ 371 Date: Jul. 18, 2023

(30) Foreign Application Priority Data
Jan. 19, 2021 (KR) 10-2021-0007334

(51) Int. Cl. B32B 3/30; B32B 3/26; B32B 5/02; B32B 5/26; B32B 7/12

(52) U.S. Cl. CPC B32B 3/30; B32B 3/266; B32B 5/022; B32B 5/265; B32B 7/12; B32B 2262/02; B32B 2307/10; B32B 2307/7265

(57) ABSTRACT

Disclosed is a waterproof sound-transmitting sheet. The waterproof sound-transmitting sheet comprises: a waterproof sound-transmitting layer having a waterproof function and configured to transmit sound; a first adhesive layer attached to the upper surface of the waterproof sound-transmitting layer; and a second adhesive layer attached to the lower surface, opposite the upper surface, of the waterproof sound-transmitting layer. The second adhesive layer includes a communication groove for communicating an inner space of the waterproof sound-transmitting layer and the space outside the waterproof sound-transmitting sheet, wherein in the inner space of the waterproof sound-transmitting layer is surrounded by the waterproof sound-transmitting layer and the second adhesive layer.

### TECHNICAL FIELD

The present disclosure relates to a waterproof sound-transmitting sheet, and more particularly, to a waterproof sound-transmitting sheet having not only high durability but also improved resilience.

### BACKGROUND ART

Recently, the use of a mobile electronic device, such as a smart phone or a smart watch, is increasing day by day. Since such a mobile electronic device is carried and used in everyday life, it requires a waterproof function. The mobile electronic device includes a sound device, such as a speaker or a microphone, and it is required to form a hole (e.g., sound hole) for passing sound therethrough on a part where the sound device is disposed. However, there is a problem in that water or dust may penetrate inside the mobile electronic device through the hole.

Accordingly, in the sound hole, a waterproof sound-transmitting sheet, which passes the sound, but blocks the water or the dust, is installed. It is required for such a waterproof sound-transmitting sheet to be manufactured in consideration of the waterproof performance and the sound transmission efficiency in all. Recently, with the improvement of the waterproof performance of the mobile electronic device, it is required for the waterproof sound-transmitting sheet to be manufactured also in consideration of the pressure resistance. In case that the pressure resistance is not considered, the waterproof sound-transmitting sheet may be damaged as an external pressure of the mobile electronic device is increased.

### SUMMARY OF INVENTION

### Technical Problem

An object of the present disclosure is to provide a waterproof sound-transmitting sheet, which is provided with a communication groove through which an air in an inner space of the waterproof sound-transmitting sheet is able to get out, and which enables the air in the inner space of the waterproof sound-transmitting sheet to flow into or out of an outer space through the communication groove.

### Solution to Problem

A waterproof sound-transmitting sheet according to embodiments of the present disclosure includes: a waterproof sound-transmitting layer having a waterproof function and configured to transmit a sound; a first adhesive layer attached to an upper surface of the waterproof sound-transmitting layer; and a second adhesive layer attached to a lower surface facing the upper surface of the waterproof sound-transmitting layer, wherein the second adhesive layer includes a communication groove configured to make an inner space of the waterproof sound-transmitting layer surrounded by the waterproof sound-transmitting layer and the second adhesive layer and an outer space of the waterproof sound-transmitting sheet communicate with each other.

### Advantageous Effects of Invention

The waterproof sound-transmitting sheet according to embodiments of the present disclosure has the effects in that since the waterproof sound-transmitting sheet is provided with the communication groove through which the air in the inner space of the waterproof sound-transmitting sheet is able to get out, the pressure in the inner space of the waterproof sound-transmitting sheet is not excessively increased even if the pressure outside the waterproof sound-transmitting sheet is increased.

The waterproof sound-transmitting sheet according to embodiments of the present disclosure has the effects in that since the waterproof sound-transmitting sheet is provided with the communication groove through which the air in the inner space of the waterproof sound-transmitting sheet is able to get out, the resilience of the waterproof sound-transmitting sheet is improved when the pressure outside the waterproof sound-transmitting sheet is changed.

### BRIEF DESCRIPTION OF DRAWINGS

FIG. 1 illustrates the shape of a waterproof sound-transmitting sheet and an electronic device to which the waterproof sound-transmitting sheet is attached according to embodiments of the present disclosure.

FIG. 2 is an exploded perspective view of a waterproof sound-transmitting sheet according to embodiments of the present disclosure.

FIG. 3 is a perspective view of a waterproof sound-transmitting sheet according to embodiments of the present disclosure.

FIG. 4 illustrates a cross section of a waterproof sound-transmitting sheet as seen along line A-A′ of FIG. 3.

FIG. 5 illustrates a cross section of a waterproof sound-transmitting sheet as seen along line B-B′ of FIG. 3.

FIG. 6 illustrates a waterproof sound-transmitting sheet according to embodiments of the present disclosure.

FIG. 7 illustrates a cross section of a waterproof sound-transmitting sheet according to embodiments of the present disclosure.

FIG. 8 illustrates a waterproof sound-transmitting sheet according to embodiments of the present disclosure.

FIG. 9 illustrates a waterproof sound-transmitting sheet according to embodiments of the present disclosure.

FIG. 10 illustrates a process of manufacturing a second adhesive layer according to embodiments of the present disclosure.

### DESCRIPTION OF EMBODIMENTS

In order to clearly describe the present disclosure, parts not related to the description will be omitted, and throughout the specification, the same reference symbols will be assigned for the same or similar constituent elements.

Although not differently defined, all terms including technical terms and scientific terms, as used herein, have the same meanings as the meanings being generally understood by those of ordinary skill in the art to which the present disclosure pertains. The terms defined in dictionaries being usually used are additionally interpreted to have the meanings matching the related technical literatures and the currently disclosed contents, and are not interpreted as the ideal or very formal meanings unless being so defined.

Hereinafter, embodiments of the present disclosure will be described in detail with reference to the accompanying drawings so that those of ordinary skill in the art to which the present disclosure pertains can easily implement the embodiments. However, the present disclosure may be implemented in various different forms, and thus is not limited to the embodiments described herein.

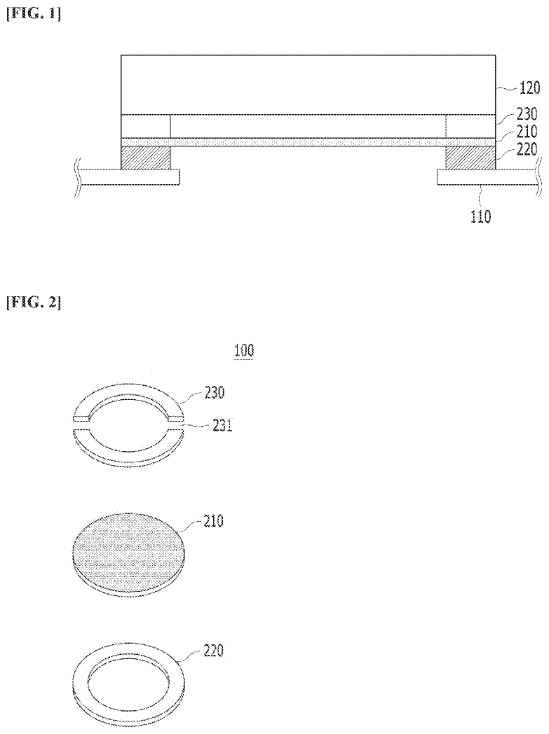

FIG. 1 illustrates the shape of a waterproof sound-transmitting sheet and an electronic device to which the waterproof sound-transmitting sheet is attached according to embodiments of the present disclosure. Referring to FIG. 1, a waterproof sound-transmitting sheet 200 may be attached to an inside of an electronic device 110, and may perform a role of transmitting a sound between an inside and an outside of the electronic device 110 while preventing liquid or foreign substances, flowing from the outside of the electronic device 110, from flowing into the inside the electronic device 110.

A first surface of the waterproof sound-transmitting sheet 200 may be attached to an inside of a housing (or case) of the electronic device 110, and a second surface thereof, which is positioned opposite to the first surface of the waterproof sound-transmitting sheet 200, may be attached to a sound module (e.g., speaker module or microphone module) 120 inside the electronic device 110. According to embodiments, the sound module may include a sound element and a circuit board on which the sound element is mounted.

According to embodiments, the waterproof sound-transmitting sheet 200 may include: a waterproof sound-transmitting layer 210 having a waterproof or dustproof function, and configured to transmit a sound; a first adhesive layer 220 configured to be attached to the electronic device 110 by being attached to a first surface of the waterproof sound-transmitting layer 210; and a second adhesive layer 230 attached to the sound module 120 by being attached to a second surface positioned to an opposite side to the first surface of the waterproof sound-transmitting layer 210.

Accordingly, the waterproof sound-transmitting sheet 200 can prevent the liquid or foreign substances, flowing from the outside of the electronic device 110, from flowing into the sound module 120. Further, the waterproof sound-transmitting sheet 200 may transmit the sound generated by the speaker module 120 to an outside (e.g., to a user), or may transmit the sound generated from the outside to the microphone module 120.

As illustrated in FIG. 1, the waterproof sound-transmitting sheet 200 is attached between the electronic device 110 and the sound module 120, and if an external pressure of the electronic device 110 is increased, an internal pressure between the waterproof sound-transmitting sheet 200 and the sound module 120 may be increased. Specifically, the pressure in the inner space surrounded by the waterproof sound-transmitting layer, the second adhesive layer 230, and the sound module 120 may be increased, and the increased pressure may act on the waterproof sound-transmitting sheet 200 to cause the waterproof sound-transmitting sheet 200 to be lengthened or damaged. In particular, if the waterproof sound-transmitting sheet 200 is kept in a lengthened state under high pressure for a long time, the waterproof sound-transmitting sheet 200 may be deformed, and as a result, the sound transmittance of the waterproof sound-transmitting sheet 200 may be reduced.

Since the waterproof sound-transmitting sheet 200 according to embodiments of the present disclosure includes a communication groove through which an air between the waterproof sound-transmitting sheet 200 and the sound module 120 is able to get out, the air in the inner space is able to flow into/out of the outer space through the communication groove even if the external pressure of the waterproof sound-transmitting sheet 200 is increased, and as a result, the pressure in the inner space of the waterproof sound-transmitting sheet 200 is not excessively increased.

The waterproof sound-transmitting sheet 200 according to embodiments of the present disclosure has the effects of not only having the pressure resistance whereby the waterproof sound-transmitting sheet 200 is not damaged even in a high-pressure environment equal to or higher than 10 bar, but also being able to return to its original shape even if the high-pressure environment is removed.

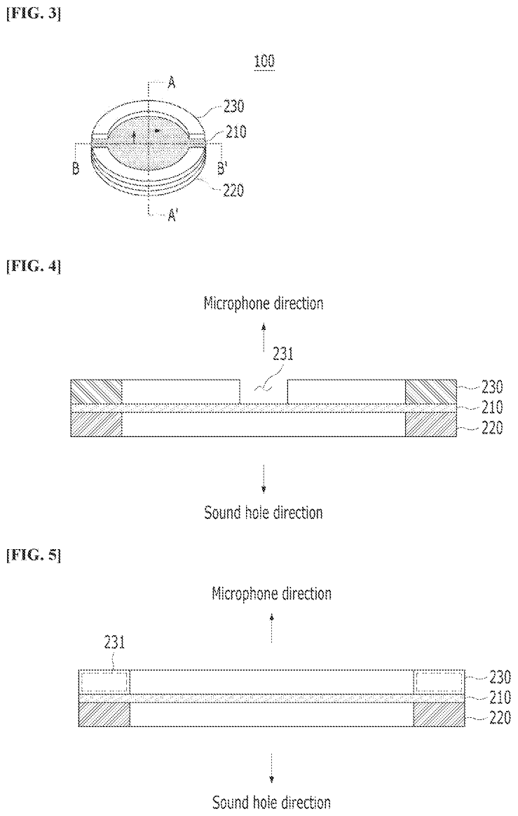

FIG. 2 is an exploded perspective view of a waterproof sound-transmitting sheet according to embodiments of the present disclosure, and FIG. 3 is a perspective view of a waterproof sound-transmitting sheet according to embodiments of the present disclosure. Referring to FIGS. 2 and 3, the waterproof sound-transmitting sheet 200 may be configured in a form in which the waterproof sound-transmitting layer 210, the first adhesive layer 220, and the second adhesive layer 230 are attached to each other.

The waterproof sound-transmitting layer 210 may be formed of a thin film having a predetermined shape. According to embodiments, the waterproof sound-transmitting layer 210 may be a thin film having various shapes, such as a circle, an ellipse, and a polygon.

The waterproof sound-transmitting layer 210 may be a thin film having a thickness of about 5 μm to 100 μm depending on the sound-transmitting and waterproof functions required in an applied device, but is not limited thereto, and according to embodiments, the waterproof sound-transmitting layer 210 may be formed with a thickness equal to or larger than 5 μm and equal to or smaller than 100 μm in consideration of the thickness of the applied electronic device.

In order to provide the waterproof performance under high water pressure, the waterproof sound-transmitting layer 210 may be made of a high elastic (high flexible) and non-porous material. For example, the waterproof sound-transmitting layer 210 may be formed of a high elastic material, such as latex, polyurethane (PU), thermoplastic poly urethane (TPU), or the like.

The waterproof sound-transmitting layer 210 according to embodiments of the present disclosure may include a non-porous membrane to provide the waterproof performance under high water pressure. For example, the waterproof sound-transmitting layer 210 may be made of a polymer material.

According to embodiments, the waterproof sound-transmitting layer 210 may be formed by forming a polymer material layer having a web structure through electrospinning of a polymer material, and then by partially dissolving the web structure of the polymer material layer.

In this case, the polymer material may include aromatic polyester, such as poly amide, polyimide, polyamideimide, poly(meta-phenylene isophthalamide), poly sulfone, polyetherketone, polyether imide, polyethylene terephthalate, polytrymethylene terephthalate, and polyethylene naphthalate, polyphosphazenes, such as polytetrafluoroethylene, polydiphenoxyphosphazene, and poly{bis [2-(2-methoxyethoxy)phosphazene]}, polyurethane copolymer including polyurethane and polyetherurethane, cellulose acetate, cellulose acetate butyrate, cellulose acetate propionate. Further, the polymer material may include polyvinylidenefluoride (PVDF), poly(vinylidenefluoride-co-hexafluoropropylene), perfluoropolymer, polyvinyl chloride or polyvinylidene chloride and copolymer thereof and polyethylene glycol derivative including polyethylene glycol dialkyl ether and polyethylene glycol dialkyl ester, polyoxide including poly(oxymethylene-oli high-oxyethylene), polyethylene oxide and polypropylene oxide, polyvinyl acetate, poly(vinylpyrrolidone-vinylacetate), polystyrene and polystyrene acrylonitrile copolymer, polyacrylonitrile copolymer including polyacrylonitrile and polyacrylonitrile methyl methacrylate copolymer, polymethylmethacrylate, polymethylmethacrylate copolymer, and mixture thereof.

In case that the waterproof sound-transmitting layer 210 includes a non-porous layer, vibrations of the sound on one side can be effectively transmitted to the other side as the thickness of the waterproof sound-transmitting layer 210 becomes thinner. Further, in case of using an electrospinning process, it is possible to make the thickness of the waterproof sound-transmitting layer 210 as thin as possible, and thus the sound transmittance can be further increased.

According to embodiments, in order to provide the waterproof performance under high water pressure, the waterproof sound-transmitting layer 210 may be made of a high elastic (high flexible) and non-porous material manufactured by methods excluding the electrospinning. As an example, the waterproof sound-transmitting layer 210 may be formed of a high elastic material, such as latex, polyurethane (PU), thermoplastic poly urethane (TPU), or the like, and may be formed in the form of a non-porous film in order to maintain the waterproof performance under the pressure equal to or higher than about 1 atmosphere.

In case that the waterproof sound-transmitting layer 210 is formed into a non-porous type, the air in the inner space of the waterproof sound-transmitting sheet 200 composed of the waterproof sound-transmitting layer 210, the second adhesive layer 230, and the sound module 120 may be difficult to easily get out into the outer space. In this case, if the external pressure of the electronic device 110 is increased (e.g., if a water pressure is applied to the electronic device 110), the external pressure acts on the inner space through the waterproof sound-transmitting layer 210. However, since the air in the inner space is unable to easily get out, the pressure in the inner space is increased. In case that the pressure in the inner space is increased, the waterproof sound-transmitting layer 210 having a relatively higher strength than the strength of the sound module 120 may be deformed or damaged.

The first adhesive layer 220 is formed of a thin film having a predetermined shape having an opening in the inside (or in the center) thereof. For example, the first adhesive layer 220 is formed of a thin film having various shapes, such as a circle, an ellipse, and a polygon, depending on the shape of the waterproof sound-transmitting layer 210. In this case, the first adhesive layer 220 may include an opening for sound transmission. For example, the first adhesive layer 220 having a ring shape having an opening in the center thereof, but embodiments of the present disclosure are not limited thereto.

The first adhesive layer 220 may be attached to the first surface (e.g., lower surface) of the waterproof sound-transmitting layer 210. According to embodiments, the first surface (e.g., lower surface) of the first adhesive layer 220 may be attached to the electronic device 110, and the second surface (e.g., upper surface) that is opposite to the first surface of the first adhesive layer 220 may be attached to the first surface (e.g., lower surface) of the waterproof sound-transmitting layer 210.

According to embodiments, the first adhesive layer 220 may be attached to an area where a sound hole formed on the electronic device 110 is formed.

The first adhesive layer 220 may be configured by joining hot melt on which the thin film and a thermoplastic resin having a cross section on which an adhesive surface is formed are formed in a pellet type or a film type. For example, the first adhesive layer 220 may be formed by laminating the hot melt and the cross-sectional adhesive film on each other.

The second adhesive layer 230 is formed of a thin film having a predetermined shape having an opening in the inside (or in the center) thereof. For example, the second adhesive layer 230 is formed of a thin film having various shapes, such as a circle, an ellipse, and a polygon, depending on the shape of the waterproof sound-transmitting layer 210. In this case, the second adhesive layer 230 may include an opening for sound transmission. For example, the second adhesive layer 230 having a ring shape having an opening in the center thereof, but embodiments of the present disclosure are not limited thereto.

The second adhesive layer 230 may be attached to the second surface (e.g., upper surface) of the waterproof sound-transmitting layer 210. According to embodiments, the first surface (e.g., lower surface) of the second adhesive layer 230 may be attached to the second surface (e.g., upper surface) of the waterproof sound-transmitting layer 210, and the second surface (e.g., upper surface) that is opposite to the first surface of the second adhesive layer 230 may be attached to the sound module 120.

According to embodiments, the second adhesive layer 230 may be attached to an area where the sound of the sound module 120 is input/output.

The second adhesive layer 230 may be configured by joining hot melt on which the thin film and a thermoplastic resin having a cross section on which an adhesive surface is formed are formed in a pellet type or a film type. For example, the second adhesive layer 230 may be formed by laminating the hot melt and the cross-sectional adhesive film on each other.

The second adhesive layer 230 according to embodiments of the present disclosure may include a communication groove 231 that makes the inner space and the outer space of the waterproof sound-transmitting sheet 200 communicate with each other. According to embodiments, the air in the inner space of the waterproof sound-transmitting sheet 200 may be discharged to the outer space through the communication groove 231, and in contrast, the air in the outer space of the waterproof sound-transmitting sheet 200 may flow into the inner space through the communication groove 231. Accordingly, even if the external pressure of the electronic device 100 is increased, the pressure in the inner space of the waterproof sound-transmitting sheet 200 is not excessively increased.

FIG. 4 illustrates a cross section of a waterproof sound-transmitting sheet as seen along line A-A′ of FIG. 3, and FIG. 5 illustrates a cross section of a waterproof sound-transmitting sheet as seen along line B-B′ of FIG. 3.

Referring to FIGS. 4 and 5, the first adhesive layer 220 and the second adhesive layer 230 are attached to both surfaces of the waterproof sound-transmitting layer 210.

The first surface (e.g., lower surface) of the first adhesive layer 220 may be attached to the electronic device 110, and the second surface (e.g., upper surface) that is opposite to the first surface of the first adhesive layer 220 may be attached to the first surface (e.g., lower surface) of the waterproof sound-transmitting layer 210. For example, the first surface of the first adhesive layer 220 may be attached to the area where the sound hole formed on the electronic device 110 is formed.

The first surface (e.g., lower surface) of the second adhesive layer 230 may be attached to the second surface (e.g., upper surface) of the waterproof sound-transmitting layer 210, and the second surface (e.g., upper surface) that is opposite to the first surface of the second adhesive layer 230 may be attached to the sound module 120. The second surface of the second adhesive layer 230 may be attached to the area where the sound of the sound module 120 is input/output.

According to embodiments, the second adhesive layer 230 may include the communication groove 231 that makes the inner space and the outer space of the waterproof sound-transmitting sheet 200 communicate with each other. For example, the communication groove 231 may make the inner space of the waterproof sound-transmitting sheet 200 surrounded by the waterproof sound-transmitting layer 210, the second adhesive layer 230, and the sound module 120 and the outer space of the waterproof sound-transmitting sheet 200 be connected (or communicate) with each other. For example, the communication groove 231 may be configured in the form of penetrating an inner periphery (i.e., inner surface) and an outer periphery (i.e., outer surface) of the second adhesive layer 230. That is, an inlet of the communication groove 231 may be formed on the inner periphery of the second adhesive layer 230, and an outlet of the communication groove 231 may be formed on the outer periphery of the second adhesive layer.

The communication groove 231 may various forms or shapes. Although FIGS. 1 to 5 illustrate that the cross section of the communication groove 231 is a quadrangle, the embodiments of the present disclosure are not limited thereto, and the communication groove 231 may have various forms, such as a circle, a polygon, and an ellipse.

According to embodiments, the width (horizontal direction in FIGS. 4 and 5) of the communication groove 231 may be larger than the height (vertical direction in FIGS. 4 and 5) of the communication groove 231. For example, the width of the communication groove 231 may be 0.1 mm to 0.5 mm, and preferably, 0.25 mm to 0.4 mm, and the height of the communication groove 231 may be 0.01 mm to 0.1 mm, and preferably, 0.03 mm to 0.05 mm.

The communication groove 231 may be formed in at least a partial area of the cross section in the vertical direction (e.g., direction in parallel to the microphone direction or a sound hole direction) of the second adhesive layer 230.

According to embodiments, the communication groove 231 may be formed to penetrate the upper surface and the lower surface of the second adhesive layer 230. Accordingly, the second adhesive layer 230 may be divided into two parts that are spaced apart from each other by the communication groove 231. That is, the second adhesive layer 230 may include a first part and a second part separated (or spaced apart) from each other by the communication groove 231.

Further, according to embodiments, the communication groove 231 may be included in the second adhesive layer 230. For example, the communication groove 231 may be formed to penetrate the inner surface and the outer surface of the second adhesive layer 230, but not to penetrate the upper surface and the lower surface thereof. Accordingly, the communication groove 231 may be formed in the form of being surrounded by the second adhesive layer 230.

The air flow between the inner space of the waterproof sound-transmitting sheet 200 and the outer space of the waterproof sound-transmitting sheet 200 becomes smooth through the communication groove 231, and if the external pressure of the electronic device 110 is increased, the air in the inner space of the waterproof sound-transmitting sheet 200 can easily get out into the outside of the waterproof sound-transmitting sheet 200, and thus the pressure in the inner space can be prevented from being excessively increased.

Accordingly, since the waterproof sound-transmitting sheet 200 according to embodiments of the present disclosure can effectively prevent the pressure in the inner space, which is formed between the waterproof sound-transmitting layer 210 and the sound module 120, from being increased, the waterproof sound-transmitting layer 210 can be prevented from being deformed, and thus the degrading of the sound-transmitting performance due to the deformation (e.g., permanent deformation) of the waterproof sound-transmitting layer 210 can be prevented.

Further, since the air flow between the inner space of the waterproof sound-transmitting sheet 200 and the outer space of the waterproof sound-transmitting sheet 200 becomes smooth through the communication groove 231, the restoration speed of the waterproof sound-transmitting layer 210 may become faster depending on the smooth air flow. In other words, in comparison to the waterproof sound-transmitting sheet in the related art, the waterproof sound-transmitting sheet 200 according to embodiments of the present disclosure can quickly restore the sensitivity loss due to the increase of the interior pressure, and as a result, the sound-transmitting performance of the waterproof sound-transmitting sheet 200 can be improved.

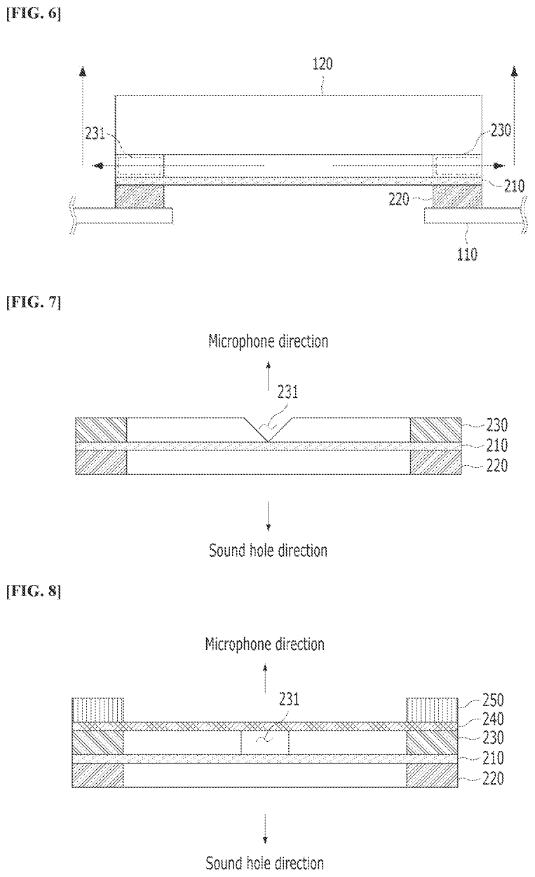

FIG. 6 illustrates a waterproof sound-transmitting sheet according to embodiments of the present disclosure. Referring to FIG. 6, the air flow inside the waterproof sound-transmitting sheet 200 is indicated by arrows.

As described above, if the external pressure of the electronic device 110 is increased, the external pressure may act on the inner space through the waterproof sound-transmitting layer 210. In this case, according to the waterproof sound-transmitting sheet 200 according to embodiments of the present disclosure, the air in the inner space of the waterproof sound-transmitting sheet 200 may get out of the waterproof sound-transmitting sheet 200 through the communication groove 231. For example, the air in the inner space of the waterproof sound-transmitting sheet 200 may get out through the communication groove 231, and then may get out through another groove formed on the electronic device 100.

Since the air in the inner space can get out through the communication groove 231, the pressure being applied by the waterproof sound-transmitting layer 210 can be dispersed even if the external pressure of the electronic device 110 is increased, and thus durability of the waterproof sound-transmitting layer 210 can be improved.

Further, since the air in the inner space can get out through the communication groove 231, the waterproof sound-transmitting layer 210 can be quickly restored even if the external pressure of the electronic device 110 is changed, and thus the sound-transmitting performance of the waterproof sound-transmitting sheet 200 is not degraded.

FIG. 7 illustrates a cross section of a waterproof sound-transmitting sheet according to embodiments of the present disclosure. FIG. 7 illustrates the cross section of the waterproof sound-transmitting sheet as seen in the same direction as the direction of FIG. 5. Referring to FIG. 7, the communication groove 231 may have a cross section in the form in which the width thereof is gradually narrowed (e.g., triangle).

According to embodiments, the communication groove 231 having the cross section described above with reference to FIG. 5 may be formed by a tool, such as a mechanical cutting machine, and the communication groove 231 having the cross section described above with reference to FIG. 7 may be formed by a tool, such as a laser cutting machine.

According to embodiments, the maximum width (in the horizontal direction in FIG. 7) of the communication groove 231 may be larger than the depth (in the vertical direction in FIG. 7) of the communication groove 231. For example, the width of the communication groove 231 may be 0.1 mm to 0.3 mm, and preferably, 0.15 mm to 0.25 mm, and the depth of the communication groove 231 may be 0.05 mm to 0.15 mm, and preferably, 0.07 mm to 0.1 mm.

FIGS. 8 and 9 illustrate a waterproof sound-transmitting sheet according to embodiments of the present disclosure. Referring to FIGS. 8 and 9, the waterproof sound-transmitting sheet 200 may further include a support layer 240 and a third adhesive layer 250.

The support layer 240 may be attached to the second adhesive layer 230, and the third adhesive layer 250 may be attached to the support layer 240. According to embodiments, the first surface (e.g., lower surface) of the second adhesive layer 230 may be attached to the second surface (e.g., upper surface) of the waterproof sound-transmitting layer 210, and the second surface (e.g., upper surface) that is opposite to the first surface of the second adhesive layer 230 may be attached to the first surface (e.g., lower surface) of the support layer 240. Further, the second surface (e.g., upper surface) of the support layer 240 may be attached to the first surface (e.g., lower surface) of the third adhesive layer 250, and the second surface (e.g., upper surface) of the third adhesive layer 250 may be attached to the sound module 120.

The support layer 240 may be formed of a thin film of a predetermined shape. According to embodiments, the support layer 240 is formed of a thin film having various shapes, such as a circle, an ellipse, a rectangle, and a hexagon, depending on the sound hole and an internal combination structure of the electronic device 110.

According to embodiments, the support layer 240 may be formed of a thin film having a thickness of about 10 μm to 100 μm, and preferably, about 15 μm to 20 μm, depending on the sound-transmitting and waterproof functions required in the applied device. Meanwhile, in case that the support layer 240 is composed of a thin film of a non-woven material, the diameter of the fiber constituting the non-woven fabric may be about 1 μm to 10 μm, and preferably, about 5 μm.

In order to prevent the waterproof sound-transmitting layer 210 from stretching beyond a predetermined level as the external pressure of the electronic device 110 is applied, the support layer 240 may be disposed to be spaced apart from the waterproof sound-transmitting layer 210 for a predetermined interval. For example, the support layer 240 forms the spacing interval with the waterproof sound-transmitting layer 210 through the thickness of the second adhesive layer 230.

The third adhesive layer 250 may be formed of a thin film of a predetermined shape having an opening in the inside (or in the center) thereof. For example, the third adhesive layer 250 is formed of a thin film having various shapes, such as a circle, an ellipse, and a polygon, depending on the shape of the waterproof sound-transmitting layer 210. In this case, the third adhesive layer 250 may include an opening for sound transmission. For example, the third adhesive layer 250 may have a ring shape having an opening in the center thereof, but the embodiments of the present disclosure are not limited thereto.

The support layer 240 being described with reference to FIG. 8 may include pores or through-holes for the sound transmission of the sound module 120.

According to embodiments, the support layer 240 may be made of a porous material on which a plurality of pores are formed. For example, the support layer 240 may be made of a porous material on which a plurality of pores are formed like a non-woven fabric formed of a material, such as polyethylene terephthalate (PET), polypropylene (PP), polyethylene (PE), or nylon. For example, on the support layer 240, a plurality of pores each having a size (diameter) of about 2 μm to 20 μm may be formed. In this case, the support layer 240 may include the pores enough to maintain an air permeability of 100 cfm or more.

According to embodiments, the support layer 240 may be formed of a non-porous material, and a discharge hole for the sound transmission with the sound module 120 may be formed on the support layer 240. For example, the discharge hole may be formed to penetrate the upper surface and the lower surface of the support layer 240.

That is, the support layer 240 being described with reference to FIG. 8 may be formed of the porous material including a plurality of pores, or may be formed of a non-porous material and include an air-communicable discharge hole.

As described above, if the external pressure of the electronic device 110 is increased, the external pressure may act on the inner space through the waterproof sound-transmitting layer 210. In this case, according to the waterproof sound-transmitting sheet 200 according to embodiments of the present disclosure, the air of the inner space of the waterproof sound-transmitting sheet 200 may get out of the waterproof sound-transmitting sheet 200 through the communication groove 231. For example, the air in the space between the support layer 240 and the sound module 120 may move into the space between the support layer 240 and the waterproof sound-transmitting layer 210 through the support layer 240, and may finally get out through the communication groove 231.

Thus, according to embodiments of the present disclosure, even if the external pressure of the electronic device 110 is increased, the pressure being applied by the waterproof sound-transmitting layer 210 can be dispersed, and accordingly, durability of the waterproof sound-transmitting layer 210 can be improved, and the waterproof sound-transmitting layer 210 can be quickly restored, so that the sound-transmitting performance of the waterproof sound-transmitting sheet 200 is not degraded.

The support layer 240 being described with reference to FIG. 9 may be formed of a non-porous material, and the third adhesive layer 250 may include a communication groove 251 that makes the inner space and the outer space of the waterproof sound-transmitting sheet 200 communicate with each other.

The communication groove 251 may make the inner space surrounded by the support layer 240, the third adhesive layer 250, and the sound module and the outer space of the waterproof sound-transmitting sheet 200 be connected (or communicate) with each other. For example, the communication groove 251 may be configured in the form of penetrating an inner periphery (i.e., inner surface) and an outer periphery (e.g., outer surface) of the third adhesive layer 250. Accordingly, since the air in the inner space surrounded by the support layer 240, the third adhesive layer 250, and the sound module can be discharged to the outer space through the communication groove 251, and thus the pressure in the inner space of the waterproof sound-transmitting sheet 200 is not excessively increased.

The explanation of the form and the shape of the communication groove 251 may be replaced by the explanation of the form and the shape of the communication groove 231 described with reference to FIGS. 1 to 7.

The communication groove 251 may be formed in at least a partial area of the cross section in the vertical direction (e.g., direction in parallel to the microphone direction or the sound hole direction) of the third adhesive layer 250.

According to embodiments, the communication groove 251 may be formed to penetrate the upper surface and the lower surface of the third adhesive layer 250. Accordingly, the third adhesive layer 250 may be divided into two parts that are spaced apart from each other by the communication groove 251. That is, the third adhesive layer 250 may include a first part and a second part separated (or spaced apart) from each other by the communication groove 251.

Further, according to embodiments, the communication groove 251 may be included in the third adhesive layer 250. For example, the communication groove 251 may be formed to penetrate the inner surface and the outer surface of the third adhesive layer 250, but not to penetrate the upper surface and the lower surface thereof. Accordingly, the communication groove 251 may be formed in the form of being surrounded by the third adhesive layer 250.

The air flow between the inner space of the waterproof sound-transmitting sheet 200 being surrounded by the support layer 240 and the third adhesive layer 250 and the outer space of the waterproof sound-transmitting sheet 200 becomes smooth through the communication groove 251, and if the external pressure of the electronic device 110 is increased, the air in the inner space of the waterproof sound-transmitting sheet 200 can easily get out into the outside of the waterproof sound-transmitting sheet 200, and thus the pressure in the inner space can be prevented from being excessively increased, so that the pressure acting on the waterproof sound-transmitting layer 210 can be dispersed.

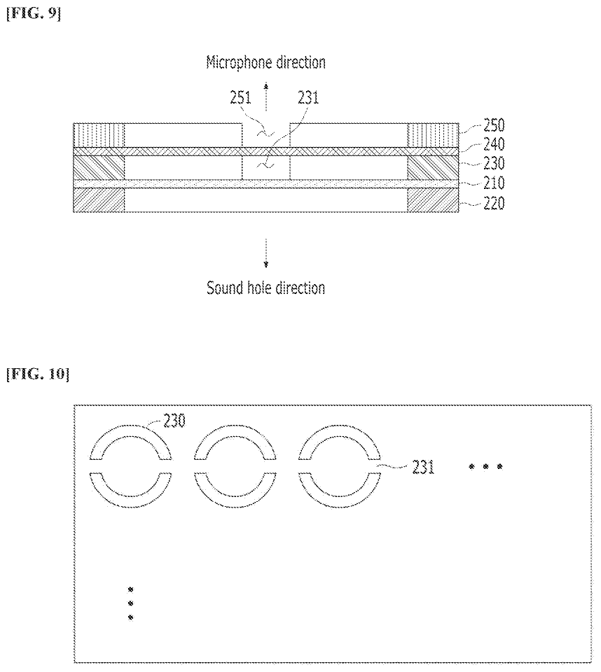

FIG. 10 illustrates a process of manufacturing a second adhesive layer according to embodiments of the present disclosure. Meanwhile, the manufacturing process being described with reference to FIG. 10 may also be applied to the manufacturing process of the third adhesive layer 250 illustrated in FIGS. 8 and 9.

Referring to FIG. 10, the second adhesive layer 230 including the communication groove 231 can be manufactured in a single process for a plurality of second adhesive layers 230. For example, in case that a plurality of second adhesive layers 230 are enumerated before the communication groove 231 is formed, the communication groove 231 for each of the second adhesive layers 230 is formed by cutting the plurality of second adhesive layers 230 at the same time, and thus the second adhesive layer 230 including the communication groove 231 can be easily manufactured in the single process.

Although preferred embodiments of the present disclosure have been described as above, various modifications are possible therefrom, and it will be understood by those of ordinary skill in the art to which the present disclosure pertains that various modified examples and correction examples can be embodied without departing from the scope of the claims of the present disclosure.

### INDUSTRIAL APPLICABILITY

The present disclosure relates to a waterproof sound-transmitting sheet.

1. A waterproof sound-transmitting sheet comprising:
a waterproof sound-transmitting layer having a waterproof function and configured to transmit a sound;
a first adhesive layer attached to an upper surface of the waterproof sound-transmitting layer; and
a second adhesive layer attached to a lower surface facing the upper surface of the waterproof sound-transmitting layer,
wherein the second adhesive layer includes a communication groove configured to make an inner space of the waterproof sound-transmitting layer surrounded by the waterproof sound-transmitting layer and the second adhesive layer and an outer space of the waterproof sound-transmitting sheet communicate with each other.

2. The waterproof sound-transmitting sheet of claim 1, wherein the waterproof sound-transmitting layer is made of a non-porous film material.

3. The waterproof sound-transmitting sheet of claim 2, wherein when a pressure is applied to an outside of the waterproof sound-transmitting sheet, an air in the inner space gets out into the outer space through the communication groove to disperse the pressure being applied to the waterproof sound-transmitting layer.

4. The waterproof sound-transmitting sheet of claim 1, wherein the second adhesive layer has a shape having an opening in the center thereof, and
wherein the communication groove is configured to penetrate an inner surface coming in contact with the opening of the second adhesive layer and an outer surface facing the inner surface.

5. The waterproof sound-transmitting sheet of claim 4, wherein the communication groove is configured to penetrate an upper surface of the second adhesive layer and a lower surface facing the upper surface.

6. The waterproof sound-transmitting sheet of claim 5, wherein the second adhesive layer comprises a first part and a second part being separated from each other by the communication groove.

7. The waterproof sound-transmitting sheet of claim 4, wherein the communication groove is disposed between an upper surface of the second adhesive layer and a lower surface facing the upper surface, and configured to be surrounded by the second adhesive layer.

8. The waterproof sound-transmitting sheet of claim 1, wherein a cross section of the communication groove is formed of any one of a circle, an ellipse, or a polygon.

9. The waterproof sound-transmitting sheet of claim 1, further comprising:
a support layer attached to an upper surface of the second adhesive layer; and
a third adhesive layer attached to an opposite surface facing a surface attached to the second adhesive layer among surfaces of the support layer.

10. The waterproof sound-transmitting sheet of claim 9, wherein the support layer comprises holes penetrating an upper surface and a lower surface of the support layer.

11. The waterproof sound-transmitting sheet of claim 9, wherein the support layer is made of a non-porous material, and
wherein the third adhesive layer includes an additional communication groove making a space surrounded by the support layer and the third adhesive layer and the outer space of the waterproof sound-transmitting sheet communicate with each other.
